(19) United States
(12) Patent Application Publication
(10) Pub. No.: US 2024/0208003 A1
(43) Pub. Date: Jun. 27, 2024

(54) SUBSTRATE POLISHING APPARATUS

(71) Applicant: EBARA CORPORATION, Tokyo (JP)

(72) Inventor: Shintaro ISONO, Tokyo (JP)

(21) Appl. No.: 18/393,232

(22) Filed: Dec. 21, 2023

(30) Foreign Application Priority Data
Dec. 26, 2022 (JP) 2022-209076

(51) Int. Cl. B24B 49/12

(52) U.S. Cl. CPC B24B 49/12

(57) ABSTRACT

To relatively easily allow monitoring of the operation of a switching device even when the switching device is employed in an optical surface monitoring system of a substrate polishing apparatus. A substrate polishing apparatus includes a polishing table, a substrate holding head, a light source, a first optical head, a switching device, a first optical line, a second optical line, a third optical line, a first optical filter, a spectroscope, and a control device. The substrate holding head is configured to hold a substrate. The first optical head is configured to project light from the light source toward the substrate held by the substrate holding head and receive light reflected from the substrate, the first optical head being disposed inside the polishing table. The switching device includes a plurality of channels. The first optical line optically connects the light source to the first optical head. The second optical line optically connects the first optical head to one channel of the plurality of channels of the switching device. The third optical line optically connects the middle of the first optical line to the middle of the second optical line. The first optical filter is disposed in the third optical line. The spectroscope is optically connected to a downstream side of the switching device. The control device is configured to receive measurement data of the intensity of a wavelength dispersed by the spectroscope. The control device is configured to monitor the operation of the switching device based on the measurement data.

### TECHNICAL FIELD

This application relates to a substrate polishing apparatus.

### BACKGROUND ART

A chemical mechanical polishing (CMP) apparatus is used to planarize a surface of a substrate in the production of semiconductor devices. Substrates used in the production of semiconductor devices often have a circular plate shape. Usually, the CMP apparatus includes a polishing table that supports a polishing pad, a substrate holding head that presses a substrate to the polishing pad, and a slurry supply nozzle that supplies slurry onto the polishing pad. While the polishing table is rotated, the slurry is supplied to the polishing pad on the polishing table, and the substrate holding head presses the substrate to the polishing pad. In the CMP apparatus, the substrate is polished by moving the substrate relatively to the polishing pad while pressing the substrate to the polishing pad in the presence of the slurry. The surface of the substrate is planarized by combination of chemical action of the slurry and mechanical action of abrasive grains contained in the slurry.

Polishing of the substrate is finished when the thickness of a film (such as an insulating film, a metallic film, and a silicon layer) constituting the surface reaches a predetermined target value. The CMP apparatus includes an optical surface monitoring system to measure the thickness of a non-metallic film such as the insulating film and the silicon layer in some cases. The optical surface monitoring system is configured to detect a surface condition of the substrate (for example, measure the film thickness of the substrate, or detect removal of the film constituting the surface of the substrate) by guiding light emitted from a light source to the surface of the substrate, measuring the intensity of reflected light from the substrate with a spectroscope, and analyzing the spectrum of the reflected light.

In the optical surface monitoring system, a switching device such as an optical switch is used in some cases. In particular, when the optical surface monitoring system includes a plurality of optical sensors, optical signals from the plurality of optical sensors are switched by the switching device and input into the spectroscope in some cases.

### CITATION LIST

### Patent Literature

PTL 1: Japanese Unexamined Patent Application Publication No. 2020-142303

PTL 2: Japanese Unexamined Patent Application Publication No. 2018-194427

PTL 3: Japanese Unexamined Patent Application Publication No. 2017-220683

### SUMMARY OF INVENTION

### Technical Problem

When an abnormality has occurred in an output of one channel of the switching device, it is not possible to immediately determine whether the abnormality has occurred in the switching device or the abnormality has occurred in a transmission line, an optical sensor, a light source, or the like that is connected to the channel of the switching device and that is located upstream. To determine these, it is necessary to stop the operation of the substrate polishing apparatus and inspect each optical element. Therefore, the operating efficiency of the substrate polishing apparatus decreases.

Therefore, it is an object of the present application to relatively easily allow monitoring of the operation of a switching device even when the switching device is employed in an optical surface monitoring system of a substrate polishing apparatus.

### Solution to Problem

According to one embodiment, a substrate polishing apparatus is provided. The substrate polishing apparatus includes a polishing table, a substrate holding head, a light source, a first optical head, a switching device, a first optical line, a second optical line, a third optical line, a first optical filter, a spectroscope, and a control device. The substrate holding head is configured to hold a substrate. The first optical head is configured to project light from the light source toward the substrate held by the substrate holding head and receive light reflected from the substrate, the first optical head being disposed inside the polishing table. The switching device includes a plurality of channels. The first optical line optically connects the light source to the first optical head. The second optical line optically connects the first optical head to one channel of the plurality of channels of the switching device. The third optical line optically connects a middle of the first optical line to a middle of the second optical line. The first optical filter is disposed in the third optical line. The spectroscope is optically connected to a downstream side of the switching device. The control device is configured to receive measurement data of intensity of a wavelength dispersed by the spectroscope. The control device is configured to monitor operation of the switching device based on the measurement data.

### BRIEF DESCRIPTION OF DRAWINGS

FIG. 1 is a schematic diagram illustrating one embodiment of a substrate polishing apparatus;

FIG. 2 is a cross-sectional view illustrating one embodiment of a detailed configuration of the substrate polishing apparatus illustrated in FIG. 1;

FIG. 3 is a schematic diagram illustrating an optical configuration of an optical surface monitoring system including a switching device according to one reference example;

FIG. 4 is a schematic diagram illustrating an optical configuration of an optical surface monitoring system including a switching device according to one embodiment;

FIG. 5 is a diagram illustrating a spectrum of light dispersed and measured by a spectroscope in the optical configuration of the reference example in FIG. 3;

FIG. 6 is a diagram illustrating a spectrum of light cut out by an optical filter;

FIG. 7 is a diagram illustrating a spectrum of light input into a channel ch1 of the switching device of the optical surface monitoring system illustrated in FIG. 4; and

FIG. 8 is a schematic diagram illustrating an optical configuration of an optical surface monitoring system including a switching device according to one embodiment.

### DESCRIPTION OF EMBODIMENTS

The following describes embodiments of a substrate polishing apparatus according to the present invention with reference to attached drawings. In the attached drawings, identical or similar reference numerals are given to identical or similar components, and in an explanation of each embodiment, overlapping explanations regarding the identical or similar components are omitted in some cases. Features indicated in each embodiment are also applicable to other embodiments as long as they do not conflict with one another.

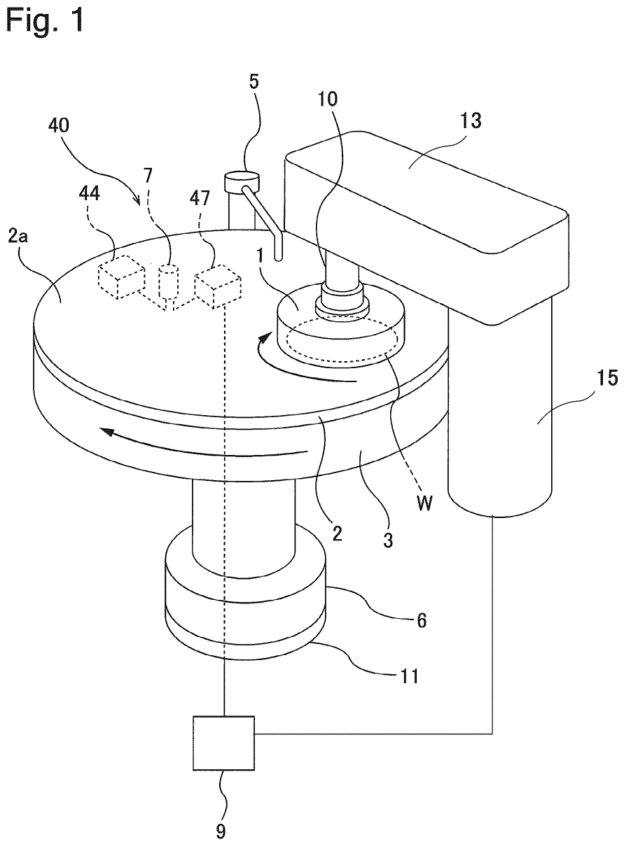

FIG. 1 is a schematic diagram illustrating one embodiment of the substrate polishing apparatus. As illustrated in FIG. 1, the substrate polishing apparatus includes a polishing table 3 that supports a polishing pad 2, a substrate holding head 1 for holding a substrate W, a table motor 6 that rotates the polishing table 3, and a slurry supply nozzle 5 for supplying slurry onto the polishing pad 2.

The substrate holding head 1 is coupled to a head shaft 10, and the substrate holding head 1 can rotate together with the head shaft 10 in a direction indicated by an arrow. As illustrated in FIG. 1, the head shaft 10 is mounted to an arm 13. The arm 13 is configured to be turnable around a support pillar 15.

The polishing table 3 is coupled to the table motor 6, and the table motor 6 is configured to rotate the polishing table 3 and the polishing pad 2 in a direction indicated by an arrow. The substrate polishing apparatus includes a rotary encoder 11 that detects a rotation angle of the polishing table 3. The rotary encoder 11 is coupled to the table motor 6.

The substrate W is polished as follows. The slurry is supplied to a polishing surface 2a of the polishing pad 2 on the polishing table 3 from the slurry supply nozzle 5 while the polishing table 3 and the substrate holding head 1 are rotated in the direction indicated by the arrow in FIG. 1. The substrate W is pressed to the polishing surface 2a of the polishing pad 2 in a state where the slurry is present on the polishing pad 2 while the substrate W is being rotated by the substrate holding head 1. Furthermore, during polishing of the substrate, the substrate holding head 1 may be swung on the polishing pad 2 by turning the arm 13. The surface of the substrate W is polished by chemical action of the slurry and mechanical action by abrasive grains included in the slurry.

The substrate polishing apparatus includes an optical surface monitoring system 40 that detects the surface condition of the substrate W. The optical surface monitoring system 40 includes an optical sensor head 7, a flash light source 44, a spectroscope 47, and a control device 9. The optical sensor head 7, the flash light source 44, and the spectroscope 47 are mounted to the polishing table 3 and integrally rotate together with the polishing table 3 and the polishing pad 2. The position of the optical sensor head 7 is a position that traverses the surface of the substrate W on the polishing pad 2 each time the polishing table 3 and the polishing pad 2 rotate once.

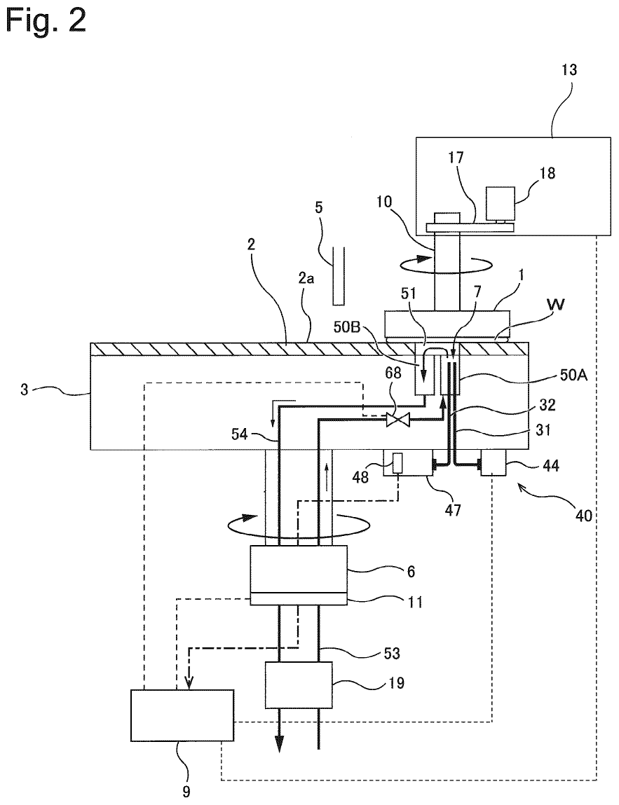

FIG. 2 is a cross-sectional view illustrating one embodiment of a detailed configuration of the substrate polishing apparatus illustrated in FIG. 1. The head shaft 10 is coupled to a substrate holding head motor 18 via a coupling device 17 such as a belt and is rotated. By the rotation of the head shaft 10, the substrate holding head 1 rotates in a direction indicated by an arrow.

The spectroscope 47 includes an optical detector 48. In one embodiment, the optical detector 48 is an image sensor such as a CCD or a CMOS. The optical sensor head 7 is optically coupled to the flash light source 44 and the optical detector 48. The optical detector 48 is electrically connected to the control device 9.

The optical surface monitoring system 40 further includes a light projection optical fiber cable 31 that guides light emitted from the flash light source 44 to the surface of the substrate W and a light reception optical fiber cable 32 that receives reflected light from the substrate W and transmits the reflected light to the spectroscope 47. A distal end of the light projection optical fiber cable 31 and a distal end of the light reception optical fiber cable 32 are located inside the polishing table 3.

The distal end of the light projection optical fiber cable 31 and the distal end of the light reception optical fiber cable 32 constitute the optical sensor head 7 that guides the light to the surface of the substrate W and receives the reflected light from the substrate W. The other end of the light projection optical fiber cable 31 is connected to the flash light source 44, and the other end of the light reception optical fiber cable 32 is connected to the spectroscope 47. The spectroscope 47 is configured to decompose the reflected light from the substrate W in accordance with wavelengths and measure the intensity of the reflected light over a predetermined wavelength range.

The flash light source 44 transmits the light to the optical sensor head 7 through the light projection optical fiber cable 31, and the optical sensor head 7 emits the light toward the substrate W. The reflected light from the substrate W is received by the optical sensor head 7 and is transmitted to the spectroscope 47 through the light reception optical fiber cable 32. The spectroscope 47 decomposes the reflected light in accordance with the wavelengths and measures the intensity of the reflected light at each wavelength. The spectroscope 47 transmits measurement data of the intensity of the reflected light to the control device 9.

The control device 9 generates a spectrum of the reflected light from the measurement data of the intensity of the reflected light. This spectrum indicates a relationship between the intensity and the wavelength of the reflected light, and the shape of the spectrum changes in accordance with the film thickness of the substrate. The control device 9 determines the film thickness of the substrate W from the spectrum of the reflected light. A known technique is used for a method for determining the film thickness of the substrate W from the spectrum of the reflected light. For example, the Fourier transformation is performed on the spectrum of the reflected light, and the film thickness is determined from an obtained frequency spectrum.

During polishing of the substrate W, each time the polishing table 3 rotates once, the optical sensor head 7 irradiates a plurality of measurement points on the substrate W with the light while traversing the surface of the substrate W on the polishing pad 2 and receives the reflected light from the substrate W. The control device 9 determines the film thickness of the substrate W from the measurement data of the intensity of the reflected light and controls the polishing operation of the substrate W based on the film thickness. For example, the control device 9 determines a polishing end point that is a time point when the film thickness of the substrate W reaches a target film thickness.

In one embodiment, the control device 9 may detect a state where a film constituting the surface of the substrate W is removed from a change in the spectrum of the reflected light. In this case, the control device 9 determines a polishing end point that is a time point when the film constituting the surface of the substrate W is removed. The control device 9 need not determine the film thickness of the substrate W from the spectrum of the reflected light.

The polishing table 3 has a first hole 50A and a second hole 50B that have an opening on its upper surface. A through hole 51 is formed at a position corresponding to these holes 50A and 50B in the polishing pad 2. The holes 50A and 50B communicate with the through hole 51, and the through hole 51 is open at the polishing surface 2a. The first hole 50A is coupled to a liquid supply line 53, and the second hole 50B is coupled to a drain line 54. The optical sensor head 7 constituted of the distal end of the light projection optical fiber cable 31 and the distal end of the light reception optical fiber cable 32 is disposed in the first hole 50A and is located below the through hole 51.

In this embodiment, a xenon flash lamp is used as the flash light source 44. The light projection optical fiber cable 31 is a light transmission portion that guides the light emitted by the flash light source 44 to the surface of the substrate W. The distal ends of the light projection optical fiber cable 31 and the light reception optical fiber cable 32 are located inside the first hole 50A and are located near a surface to be polished of the substrate W. The optical sensor head 7 constituted of each distal end of the light projection optical fiber cable 31 and the light reception optical fiber cable 32 is disposed to face the substrate W held by the substrate holding head 1. Each time the polishing table 3 rotates, the plurality of measurement points on the substrate W are irradiated with the light. In this embodiment, while only one optical sensor head 7 is disposed, a plurality of optical sensor heads 7 may be disposed.

During polishing of the substrate W, the optical sensor head 7 travels across the substrate W each time the polishing table 3 rotates once. While the optical sensor head 7 is below the substrate W, the flash light source 44 emits the light at predetermined intervals. The light is guided to the surface (the surface to be polished) of the substrate W through the light projection optical fiber cable 31, and the reflected light from the substrate W is received by the spectroscope 47 through the light reception optical fiber cable 32 and is captured in the optical detector 48. The optical detector 48 measures the intensity of the reflected light at each wavelength over the predetermined wavelength range and transmits the obtained measurement data to the control device 9. The measurement data is a film thickness signal varying in accordance with the film thickness of the substrate W. The control device 9 generates the spectrum of the reflected light that represents the intensity of the light for each wavelength from the measurement data and further determines the film thickness of the substrate W from the spectrum of the reflected light.

During polishing of the substrate W, as a rinse liquid, pure water is supplied to the first hole 50A via the liquid supply line 53 and further supplied to the through hole 51 through the first hole 50A. The pure water fills space between the surface (the surface to be polished) of the substrate W and the optical sensor head 7. The pure water flows into the second hole 50B and is discharged through the drain line 54. The pure water flowing inside the first hole 50A and the through hole 51 prevents the slurry from entering the first hole 50A, and this ensures an optical path.

The liquid supply line 53 and the drain line 54 are connected to a rotary joint 19 and further extend inside the polishing table 3. One end of the liquid supply line 53 is connected to the first hole 50A. The other end of the liquid supply line 53 is connected to a pure water supply source that is not illustrated. The pure water is supplied to the first hole 50A through the liquid supply line 53 and further supplied to the through hole 51 through the first hole 50A.

One end of the drain line 54 is connected to the second hole 50B. The pure water supplied to the through hole 51 flows through the second hole 50B and further is discharged outside the substrate polishing apparatus through the drain line 54. An open/close valve 68 is mounted to the liquid supply line 53. The open/close valve 68 is an electromagnetic valve or an electric valve. The open/close valve 68 is electrically connected to the control device 9. During polishing of the substrate W, the control device 9 periodically opens and closes the open/close valve 68 in synchronization with the rotation of the polishing table 3. Specifically, the control device 9 closes the open/close valve 68 when the substrate W is not present on the through hole 51, and the control device 9 opens the open/close valve 68 when the substrate W is present on the through hole 51.

The above-described embodiment is an example of a so-called water seal type in which the space between the surface (the surface to be polished) of the substrate W and the optical sensor head 7 is filled with pure water. As another embodiment, instead of using the water seal type that supplies water inside the through hole to secure the optical path, a configuration in which a polishing pad having a transparent window is attached to the polishing table 3 may be employed. For example, a method using a transparent window is disclosed in Japanese Unexamined Patent Application Publication No. 2017-220683 (PTL 3).

The rotary encoder 11 is electrically connected to the control device 9, and an output signal (that is, a detected value of the rotation angle of the polishing table 3) of the rotary encoder 11 is transmitted to the control device 9. The control device 9 determines a relative position of the optical sensor head 7 relative to the substrate holding head 1 from the output signal of the rotary encoder 11, that is, the rotation angle of the polishing table 3 and controls light emission timing of the flash light source 44 and light detection timing of the optical detector 48 based on the relative position of the optical sensor head 7. In another embodiment, the control device 9 may control operation timing of the flash light source 44 and the optical detector 48 by detecting the rotation angle (the relative position) of the polishing table 3 with a dog and a light shielding sensor mounted to the polishing table 3.

During polishing of the substrate W, the control device 9 issues a command to the flash light source 44 and the optical detector 48 to control light emission operation of the flash light source 44 and light detection operation of the optical detector 48. Namely, when the optical sensor head 7 is present below the substrate W, the control device 9 transmits a light emission trigger signal to the flash light source 44 and transmits a light detection trigger signal to the optical detector 48. When receiving the light emission trigger signal, the flash light source 44 instantaneously emits light. When receiving the light detection trigger signal, the optical detector 48 starts capturing the reflected light, and when the transmission of the light detection trigger signal is halted, the optical detector 48 halts capturing of the reflected light.

The control device 9 generates the light emission trigger signal and the light detection trigger signal that are synchronized with one another. While the optical sensor head 7 is traveling across the substrate W, the flash light source 44 emits light multiple times by receiving a plurality of light emission trigger signals, and simultaneously the optical detector 48 captures the reflected light from the substrate W multiple times by receiving a plurality of light detection trigger signals. While the optical sensor head 7 is traveling across the substrate W, the number of light emission trigger signals that the flash light source 44 receives is larger than the number of light detection trigger signals that the optical detector 48 receives. Namely, while the optical sensor head 7 is traveling across the substrate W, the flash light source 44 emits light more often than the optical detector 48 captures the reflected light.

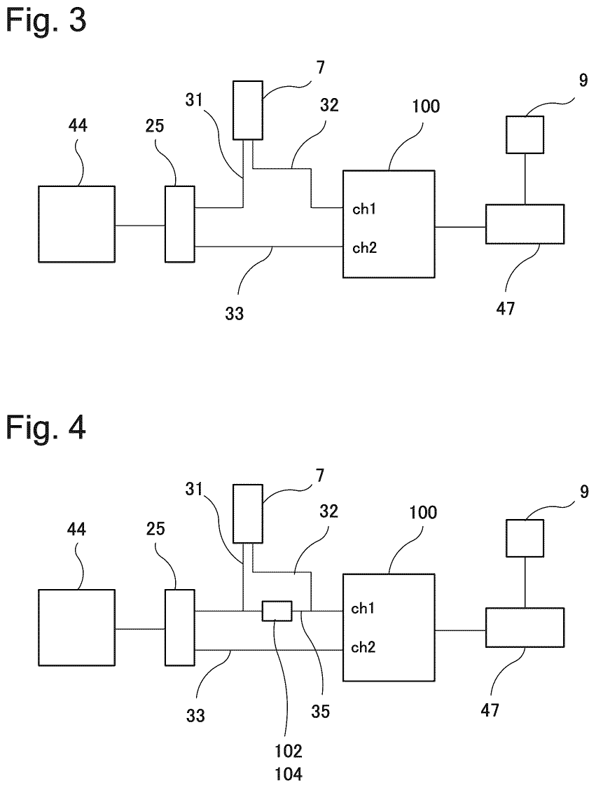

FIG. 3 is a schematic diagram illustrating an optical configuration of the optical surface monitoring system 40 including a switching device according to one reference example. In the example illustrated in FIG. 3, the light from the flash light source 44 is received by an optical fiber bundle 25. A part of the light from the flash light source 44 is guided to the optical sensor head 7 through the light projection optical fiber cable 31. The light reflected from the substrate W is input into a channel ch1 of a switching device 100 through the light reception optical fiber cable 32. The light input into the channel ch1 is dispersed by the spectroscope 47, the intensity of the reflected light at each wavelength is measured over the predetermined wavelength range, and the obtained measurement data are transmitted to the control device 9. A part of the light from the flash light source 44 is input into a channel ch2 of the switching device 100 through a light source monitoring fiber cable 33. The channel ch2 of the switching device 100 can be used for monitoring the flash light source 44.

In one embodiment, the switching device 100 can be an optical switch. The optical switch can be a type in which a specific optical path is driven by an actuator to selectively connect the specific optical path to one of a plurality of optical paths. The switching device 100 may be a type that leaves one of the plurality of optical paths and blocks the other optical paths with a shutter.

For example, assume that in the configuration according to the reference example in FIG. 3, there is an abnormality in an output of the channel ch1. In this case, it is not possible to determine whether there is an abnormality in the switching device 100 itself or there is an abnormality in the light reception optical fiber cable 32, the light projection optical fiber cable 31, and the optical sensor head 7, which are upstream. Therefore, when there is an abnormality in the output of the channel ch1 of the switching device 100, since it is necessary to halt the operation of the substrate polishing apparatus including the optical surface monitoring system 40 and investigate an abnormal portion, the operating efficiency of the substrate polishing apparatus decreases.

FIG. 4 is a schematic diagram illustrating an optical configuration of the optical surface monitoring system 40 including a switching device according to one embodiment. In the optical configuration illustrated in FIG. 4, a bypass fiber cable 35 that optically connects the middle of the light projection optical fiber cable 31 to the middle of the light reception optical fiber cable 32 is disposed. In one embodiment, an optical filter 102 is disposed in the bypass fiber cable 35. In one embodiment, the optical filter 102 can be an optical filter that transmits only a part of the wavelength width of the light from the flash light source 44. The optical filter 102 can be configured of a band pass filter, a long pass filter, a short pass filter, and a color filter that are commercially available, and a combination of them. In one embodiment, instead of the optical filter 102 that transmits only a part of the wavelength width of the light, a light blocking filter 104 that blocks all wavelengths included in the flash light source 44 may be disposed.

By using the optical surface monitoring system 40 illustrated in FIG. 4, it is possible to monitor the operation of the switching device 100 as follows. The substrate W is irradiated with the light from the flash light source 44 through the light projection optical fiber cable 31, the light reflected from the substrate W is input into the channel ch1 of the switching device 100 through the light reception optical fiber cable 32 and is dispersed by the spectroscope 47, and the intensity of the reflected light at each wavelength is measured over the predetermined wavelength range.

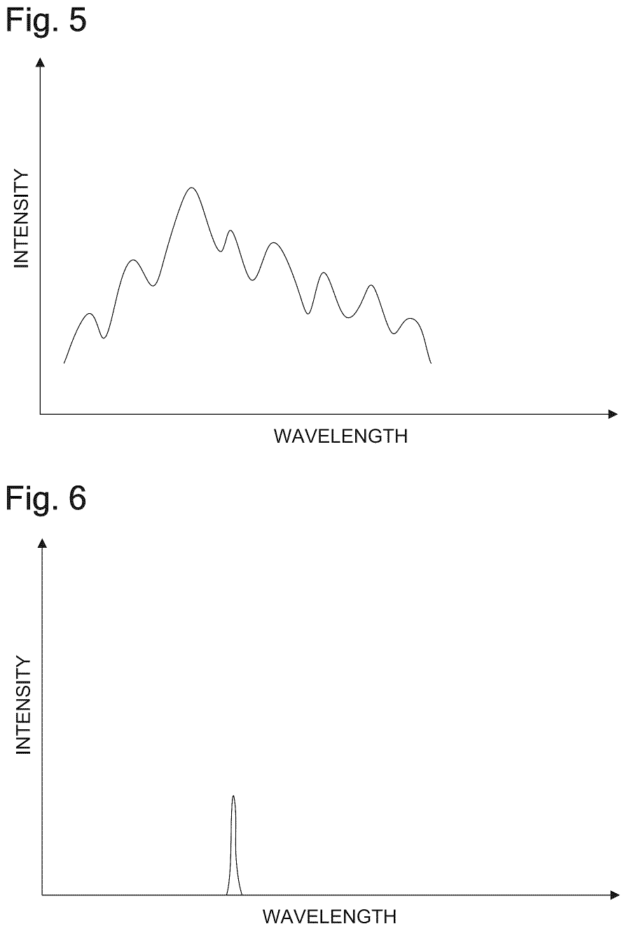

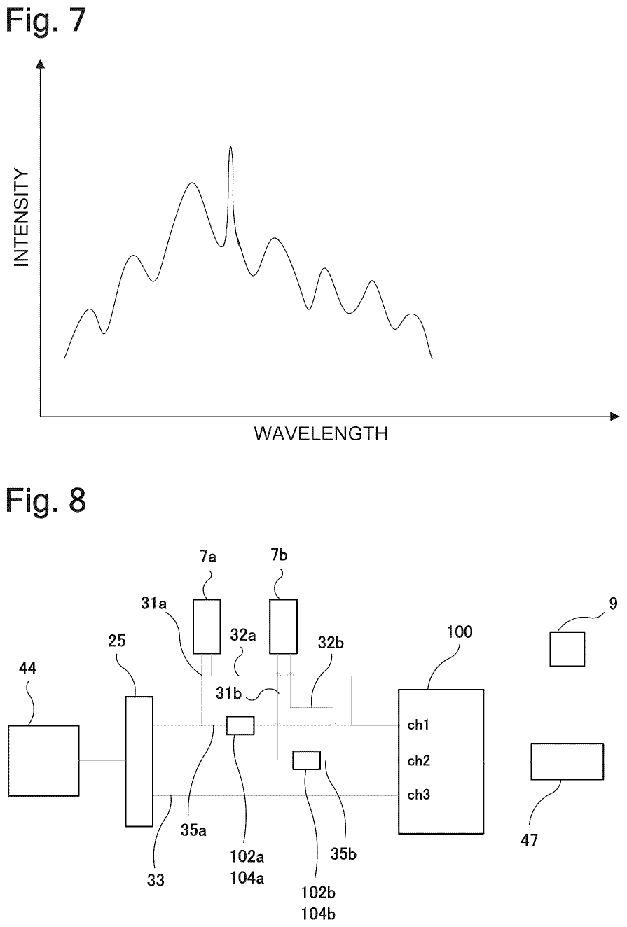

FIG. 5 is a diagram illustrating a spectrum of the light dispersed and measured by the spectroscope 47, regarding the reflected light that has passed through the light reception optical fiber cable 32 during polishing of the substrate, in the optical configuration of the reference example in FIG. 3. From the spectrum as is illustrated in FIG. 5, the control device 9 can determine the film thickness of the substrate W. In the optical surface monitoring system 40 illustrated in FIG. 4, the bypass fiber cable 35 that branches from the middle of the light projection optical fiber cable 31 is present. In the optical configuration illustrated in FIG. 4, the light having branched in the middle of the light projection optical fiber cable 31 passes through the bypass fiber cable 35 and is connected to the light reception optical fiber cable 32. The light passing through the bypass fiber cable 35 is cut out only in a specific wavelength width by the optical filter 102. FIG. 6 is a diagram illustrating a spectrum of the light cut out by the optical filter 102. Therefore, in the optical surface monitoring system 40 illustrated in FIG. 4, the light having received by the optical sensor head 7 and having passed through the light reception optical fiber cable 32 (FIG. 5) and the light having passed through the bypass fiber cable 35 (FIG. 6) are combined and input into the channel ch1 of the switching device 100. FIG. 7 is a diagram illustrating a spectrum of the light input into the channel ch1 of the switching device 100 of the optical surface monitoring system 40 illustrated in FIG. 4.

In one embodiment, in determining the film thickness of the substrate W, it is possible to determine the film thickness of the substrate W by excluding the specific wavelength width cut out by the optical filter 102 from the spectrum illustrated in FIG. 7. Since the specific wavelength width cut out by the optical filter 102 has a narrow range, even when the specific wavelength width is not used, there is little influence in determining the film thickness of the substrate W. Alternatively, in determining the film thickness of the substrate W, the film thickness of the substrate W may be determined by complementing the spectrum of the specific wavelength width cut out by the optical filter 102 with the surrounding spectrum.

On the other hand, the operation of the switching device 100 can be monitored by monitoring the intensity of the light of the specific wavelength width cut out by the optical filter 102. For example, assume that an abnormal output is detected on the channel ch1 of the switching device 100 while the film thickness of the substrate W is being measured. At that time, if no abnormality is recognized in the intensity of the light of the specific wavelength width cut out by the optical filter 102, it can be assumed that there is no abnormality in the switching device 100 itself. In this case, it is suspected that there is an abnormality in the optical sensor head 7. When an abnormality is recognized in the intensity of the light of the specific wavelength width cut out by the optical filter 102, and there is no abnormality in an output of the channel ch2, it is assumed that there is no abnormality in the flash light source 44, and there is an abnormality in the switching device 100. The operation of the switching device 100 may be monitored by comparing the optical intensity of the specific wavelength width cut out by the optical filter 102 with the optical intensity of other wavelengths.

Thus, in the above-described embodiment, while measuring the film thickness of the substrate W, the operation of the switching device 100 can be simultaneously monitored. Namely, in polishing and film thickness measurement of the substrate W, it can be confirmed that no abnormality has occurred in the switching device 100. By monitoring the light from the bypass fiber cable 35, when there is an abnormality in the output, it is possible to more specifically identify an abnormal portion. The control device 9 may be configured to issue an alarm signal when detecting an abnormality in the operation of the switching device 100. An alarm can be an audio signal, a screen display on a user interface of the substrate polishing apparatus, or the like.

The operation of the switching device 100 does not have to be monitored simultaneously with the measurement of the surface condition of the substrate W using the optical sensor head 7. The operation of the switching device 100 may be confirmed when the polishing of the substrate W is not being performed in the substrate polishing apparatus. For example, the operation of the switching device 100 can be confirmed when the substrate polishing apparatus is on standby, or during a period from the end of polishing of one substrate W to the start of polishing of the next substrate W. By confirming the operation of the switching device 100 during transportation of the substrate W, the operation of the switching device 100 can be confirmed without decreasing the operating efficiency of the substrate polishing apparatus. When the operation of the switching device 100 is not monitored simultaneously with the film thickness measurement of the substrate W, in performing the film thickness measurement of the substrate, the above-described light blocking filter 104 may be disposed in the bypass fiber cable 35 instead of the optical filter 102 that transmits only a part of the wavelength width of the light. By using the light blocking filter 104, it is possible to prevent the light from the bypass fiber cable 35 from being combined and input into the channel ch1 of the switching device 100. When the operation of the switching device 100 is not monitored simultaneously with the film thickness measurement of the substrate W, there may be a case where the light entering from the optical sensor head 7 becomes noise. Therefore, in one embodiment, when the operation of the switching device 100 is confirmed, the operation of the switching device 100 may be confirmed in a state where the optical sensor head 7 is covered by the substrate holding head 1 that does not hold the substrate and no light enters the optical sensor head 7.

FIG. 8 is a schematic diagram illustrating an optical configuration of the optical surface monitoring system 40 including a switching device according to one embodiment. In the optical configuration illustrated in FIG. 8, there are two optical sensor heads 7. As one embodiment, there may be two or more optical sensor heads 7. In the embodiment illustrated in FIG. 8, one optical sensor head 7a can be a sensor that measures the film thickness at a center portion of the substrate W, and another optical sensor head 7b can be a sensor that measures the film thickness at an edge portion of the substrate W. As illustrated in FIG. 8, a bypass fiber cable 35a that optically connects the middle of a light projection optical fiber cable 31a to the middle of a light reception optical fiber cable 32a is disposed. In one embodiment, an optical filter 102a or a light blocking filter 104a is disposed in the bypass fiber cable 35a.

As illustrated in FIG. 8, a bypass fiber cable 35b that optically connect the middle of a light projection optical fiber cable 31b to the middle of a light reception optical fiber cable 32b is disposed. In one embodiment, an optical filter 102b or a light blocking filter 104b is disposed in the bypass fiber cable 35b.

In the embodiment illustrated in FIG. 8, the light reception optical fiber cable 32a is connected to the channel ch1 of the switching device 100, and the light reception optical fiber cable 32b is connected to the channel ch2 of the switching device 100. The light source monitoring fiber cable 33 is connected to a channel ch3 of the switching device 100.

In the embodiment illustrated in FIG. 8, the optical filter 102a and the optical filter 102b can be optical filters that cut out different wavelength widths. By using the optical filters that cut out different wavelength widths, it is possible to monitor the optical intensity of the wavelength width of the optical filter corresponding to each channel of the switching device 100, and thus, individually confirm the operation of each channel of the switching device 100.

According to the embodiment in FIG. 8, similarly to the embodiment in FIG. 4, the operation of the switching device 100 can be monitored. Also in the embodiment illustrated in FIG. 8, the operation of the switching device 100 can be simultaneously monitored while the surface condition of the substrate W is being measured using the optical sensor head 7. Also in the embodiment illustrated in FIG. 8, the operation of the switching device 100 does not have to be monitored simultaneously with the measurement of the surface condition of the substrate W using the optical sensor head 7.

In the embodiment illustrated in FIG. 8, by using an optical filter cutting out a different wavelength width from the optical filter 102a and the optical filter 102b, the operation of the switching device 100 can be monitored with different wavelengths for each channel. When two or more optical sensor heads 7 are used, by using the optical filters 102 that cut out different wavelength widths for the respective bypass fiber cables 35, the operation of the switching device 100 can be monitored with different wavelengths for each channel.

In one embodiment, an optical filter may be disposed in the light source monitoring fiber cable 33. The optical filter disposed in the light source monitoring fiber cable 33 can be one that passes only a specific wavelength width. For example, the optical filter disposed in the light source monitoring fiber cable 33 can be an optical filter that cuts out a different wavelength width from the optical filter 102 in FIG. 4 and the optical filters 102a, 102b in FIG. 8.

In the embodiments illustrated in FIG. 4 and FIG. 8, a continuous light source that always emits light may be used instead of the flash light source 44. When the continuous light source is used, a capturing time of the reflected light from the substrate W is controlled by operation timing of the optical detector 48.

While several embodiments of the present invention have been described above, the above-described embodiments of the present invention are intended to facilitate understanding of the present invention and do not limit the present invention. The present invention may be modified and improved without departing from its spirit, and it goes without saying that the present invention includes equivalents of the present invention. To the extent that at least part of the above-described problems can be solved, or to the extent that at least part of the effect is achieved, any combination or omission of each component described in the claims and specification is possible.

From the above-described embodiments, at least the following technical ideas are obtained.

### [Configuration 1]

According to a configuration 1, a substrate polishing apparatus is provided. The substrate polishing apparatus includes a polishing table, a substrate holding head, a light source, a first optical head, a switching device, a first optical line, a second optical line, a third optical line, a first optical filter, a spectroscope, and a control device. The substrate holding head is configured to hold a substrate. The first optical head is configured to project light from the light source toward the substrate held by the substrate holding head and receive light reflected from the substrate, the first optical head being disposed inside the polishing table. The switching device includes a plurality of channels. The first optical line optically connects the light source to the first optical head. The second optical line optically connects the first optical head to one channel of the plurality of channels of the switching device. The third optical line optically connects a middle of the first optical line to a middle of the second optical line. The first optical filter is disposed in the third optical line. The spectroscope is optically connected to a downstream side of the switching device. The control device is configured to receive measurement data of intensity of a wavelength dispersed by the spectroscope. The control device is configured to monitor operation of the switching device based on the measurement data.

### [Configuration 2]

According to a configuration 2, the substrate polishing apparatus according to the configuration 1 further includes a second optical head, a fourth optical line, a fifth optical line, a sixth optical line, and a second optical filter. The second optical head is configured to project light from the light source toward the substrate held by the substrate holding head and receive light reflected from the substrate, the second optical head being disposed inside the polishing table. The fourth optical line optically connects the light source to the second optical head. The fifth optical line optically connects the second optical head to other one channel of the plurality of channels of the switching device. The sixth optical line optically connects a middle of the fourth optical line to a middle of the fifth optical line. The second optical filter is disposed in the sixth optical line.

### [Configuration 3]

According to a configuration 3, in the substrate polishing apparatus according to the configuration 1, the first optical filter is configured to transmit only a specific wavelength width.

### [Configuration 4]

According to a configuration 4, in the substrate polishing apparatus according to the configuration 2, the first optical filter is configured to transmit only a first wavelength width. The second optical filter is configured to transmit only a second wavelength width different from the first wavelength width.

### [Configuration 5]

According to a configuration 5, in the substrate polishing apparatus according to any one configuration of the configuration 1 to the configuration 4, the first optical filter is configured to block all the wavelengths included in the light source.

### [Configuration 6]

According to a configuration 6, in the substrate polishing apparatus according to any one configuration of the configuration 1 to the configuration 5, the control device is configured to determine a surface condition of the substrate held by the substrate holding head based on the measurement data and monitor the operation of the switching device based on the measurement data.

### [Configuration 7]

According to a configuration 7, in the substrate polishing apparatus according to any one configuration of the configuration 1 to the configuration 6, the control device is configured to control operation of the substrate holding head. The control device is configured to monitor the operation of the switching device based on the measurement data in a state where the optical head is covered by the substrate holding head by which the substrate is unheld.

This application claims priority under the Paris Convention to Japanese Patent Application No. 2022-209076 filed on Dec. 26, 2022, which is incorporated herein by reference in its entirety.

### REFERENCE SIGNS LIST

1 . . . substrate holding head
2 . . . polishing pad
3 . . . polishing table
7 . . . optical sensor head
9 . . . control device
31 . . . light projection optical fiber cable
32 . . . light reception optical fiber cable
33 . . . light source monitoring fiber cable
35 . . . bypass fiber cable
40 . . . optical surface monitoring system
44 . . . flash light source
47 . . . spectroscope
48 . . . optical detector
100 . . . switching device
102 . . . optical filter
104 . . . light blocking filter
W . . . substrate

What is claimed is:

1. A substrate polishing apparatus comprising:
a polishing table;
a substrate holding head configured to hold a substrate;
a light source;
a first optical head configured to project light from the light source toward the substrate held by the substrate holding head and receive light reflected from the substrate, the first optical head being disposed inside the polishing table;
a switching device including a plurality of channels;
a first optical line optically connecting the light source to the first optical head;
a second optical line optically connecting the first optical head to one channel of the plurality of channels of the switching device;
a third optical line optically connecting a middle of the first optical line to a middle of the second optical line;
a first optical filter disposed in the third optical line;
a spectroscope optically connected to a downstream side of the switching device; and
a control device configured to receive measurement data of intensity of a wavelength dispersed by the spectroscope, wherein
the control device is configured to monitor operation of the switching device based on the measurement data.

2. The substrate polishing apparatus according to claim 1, further comprising:
a second optical head configured to project light from the light source toward the substrate held by the substrate holding head and receive light reflected from the substrate, the second optical head being disposed inside the polishing table;
a fourth optical line optically connecting the light source to the second optical head;
a fifth optical line optically connecting the second optical head to other one channel of the plurality of channels of the switching device;
a sixth optical line optically connecting a middle of the fourth optical line to a middle of the fifth optical line; and
a second optical filter disposed in the sixth optical line.

3. The substrate polishing apparatus according to claim 1, wherein
the first optical filter is configured to transmit only a specific wavelength width.

4. The substrate polishing apparatus according to claim 2, wherein
the first optical filter is configured to transmit only a first wavelength width, and
the second optical filter is configured to transmit only a second wavelength width different from the first wavelength width.

5. The substrate polishing apparatus according to claim 1, wherein
the first optical filter is configured to block all the wavelengths included in the light source.

6. The substrate polishing apparatus according to claim 4, wherein
the control device is configured to determine a surface condition of the substrate held by the substrate holding head based on the measurement data and monitor the operation of the switching device based on the measurement data.

7. The substrate polishing apparatus according to claim 1, wherein
the control device is configured to control operation of the substrate holding head, and
the control device is configured to monitor the operation of the switching device based on the measurement data in a state where the optical head is covered by the substrate holding head by which the substrate is unheld.
